(19) United States
(12) Patent Application Publication
(10) Pub. No.: US 2026/0211074 A1
(43) Pub. Date: Jul. 23, 2026

(54) A METHOD FOR FAULT DETECTION OR CALIBRATION IN AN UNSUBMERGED STATE OF AN ELECTRO-MAGNETIC MEASURING SYSTEM ARRANGED ON AN UNDERWATER SENSOR PLATFORM AND A SYSTEM FOR FAULT DETECTION AND CALIBRATION OF AN ELECTRO-MAGNETIC MEASURING SYSTEM ARRANGED ON AN UNDERWATER SENSOR PLATFORM

(71) Applicant: Kongsberg Discovery AS, Horten (NO)

(72) Inventor: Philip HEELAN, Asker (NO)

(21) Appl. No.: 19/142,038

(22) PCT Filed: Dec. 21, 2023
(86) PCT No.: PCT/NO2023/060133

§ 371 Date: Jun. 20, 2025

(30) Foreign Application Priority Data
Dec. 23, 2022 (NO) 20221404

(51) Int. Cl. G01R 35/00; B63G 8/00; G01R 29/12

(52) U.S. Cl. CPC G01R 35/007; B63G 8/001; G01R 29/12; B63G 2008/004

(57) ABSTRACT

The disclosure relates to a method for fault detection or calibration in an unsubmerged state of an electro-magnetic measuring system arranged on an underwater sensor platform, the method comprising the steps of providing an underwater sensor platform comprising an electro-magnetic measuring system, wherein the electro-magnetic measuring system comprising: one or more electrode pairs for measuring electromagnetic fields across said electrode pairs, a power source, a wire harness and a first controller module configured for data gathering and/or processing, the wire harness connecting the first controller module to the one or more electrode pairs, the method comprising the following steps: providing one or more pair of containers comprising an electrode material, and a function generator acting as a second controller module/processing unit and source for providing signal patterns. The disclosure further relates to a system for fault detection and calibration of an electro-magnetic measuring system arranged on an autonomous underwater sensor platform.

### TECHNICAL FIELD

The present disclosure relates to a method for fault detection and calibration of an electro-magnetic measuring system arranged on an underwater sensor platform and a system for fault detection and calibration of an electrode, measuring system arranged on an underwater sensor platform. More specifically, the disclosure relates to a method for fault detection and calibration of an electro-magnetic measuring system arranged on an underwater sensor platform and a system for fault detection and calibration of an electro-magnetic measuring system arranged on an underwater sensor platform as defined in the introductory parts of the independent claims.

### BACKGROUND ART/PROBLEM

A problem with underwater sensor platforms and electronics used in measuring electro-magnetic fields are that they frequently operating in harsh environments, such as waters with high salinity, pollution, debris and/or other. This leads to accelerated deterioration of exposed parts of the equipment, and leads to uncertain survey results.

Also wire harness of such underwater sensor platform equipment is often plentiful, and during installation, maintenance and reparations/replacements such wire harness reconnecting process represent a certain risk for being wrongly connected.

When the equipment comprises electrodes measuring electromagnetic field in water, it is not a trivial case to test such equipment before the equipment is deployed, and faults appearing under deployment is hard to detect. There is thus a need for an improved testing and calibration toolset for underwater sensor platforms comprising electrode sensors.

It is further a problem for underwater sensor platforms that they operate in waters where background noise may be substantial. Background noise may distort any measurements made by measuring electrodes.

It is further a challenge to assess the conductive properties of the fluid wherein deployment is planned correctly, as these may change substantially from location to location. Pollution and salinity level are example on parameters that may change the conductive properties of water.

### SUMMARY

It is an object of the present disclosure to mitigate, alleviate or eliminate one or more of the above-identified problems and challenges, and solve at least some of the above mentioned problems and challenges. According to a first aspect there is provided a method for fault detection and calibration of an electro-magnetic measuring system arranged on an underwater sensor platform, the method comprising the steps: providing an electro-magnetic measuring system in an underwater sensor platform, wherein the electro-magnetic measuring system comprising: a first one or more electrode pairs for injecting a controlled current signal into ambient water/conductive fluid, a second one or more electrode pairs for measuring electromagnetic fields across the electrode pairs, a power source, a wire harness assembly and a controller module for connecting to and controlling the first and second electrode pairs and data processing, a constant current source, powered by the power source, for providing a current to the first one or more electrode pairs, the method comprising

the following steps:
providing an on deck testing and calibration system comprising a pair of containers (50, 50′) mounted to any of the second one or more electrode pairs (2, 2′), wherein the containers (50, 50′) are filled with a conductive fluid (51, 51′), such that the electrodes (2, 2′) are fully surrounded by the conductive fluid (51, 51′), and further connecting a source electrode pair (3) and an embedded container source electrode/metal pin (3″) in each containers (50, 50′) via a connecting line (30), or
deploying the underwater sensor platform into the sea, and
injecting a controlled voltage or controlled current signal into ambient water/conductive fluid with the first one or more electrode pairs.

The advantage with present disclosure is that is provided a self-contained/self-sustained method that can test itself during deployment by injecting a test signal in the form of a constant current signal into the ambient waters. Such that a known electromagnetic field around the underwater sensor platform may be used for calibration and testing.

According to some embodiments, the first one or more electrode pairs is one of:
one of the second one or more electrode pairs when there are more than one such electrode pairs provided on the underwater sensor platform, and
a dedicated pair of electrodes used for injecting a current signal into ambient water.

When the underwater sensor platform has more than one pair of electrodes for measuring electromagnetic fields, it is provided a possibility for using one of the pairs of electrodes for measuring electromagnetic fields for injecting the test signal into the ambient waters. Thus by altering which electrode pair sending the test signal, all electrode pairs may be evaluated, even when a dedicated electrode pair for injecting a current signal into ambient water is not installed in the underwater sensor platform.

According to some embodiments, the method comprises the steps:
measuring a background noise signal with the second one or more electrode pairs before injection of a constant current signal into ambient water,
providing the constant current signal as a distinctive digital signal pattern,
adjusting the constant current signal strength to a level above the background noise such that an acceptable SNR is achieved,
measuring an electromagnetic field with the second one or more electrode pairs,
filtering the measured electromagnetic field to detect the distinctive digital signal pattern.

The underwater sensor platform is prepared for operation in a variety of environments, all which contributes to a background noise. It is provided for a feature taking the background noise into account, by adjusting the constant current signal strength to a level above the background noise to achieve an acceptable signal noise ratio, SNR, for analysis.

According to some embodiments, the method comprises the step: analyzing the filtered measured electromagnetic field, wherein for each of the second one or more electrode pair the analysis of the filtered measured electromagnetic field comprise detecting one or more of:
an erroneously connected electrode,
a deteriorated or faulty harness assembly
an erroneously wired harness assembly
deterioration of the electrodes, and
changed characteristics in the ambient water.

According to some embodiments, the method comprises the step: analyzing the filtered measured electromagnetic field, wherein for each of the one or more electrode pair the analysis of the filtered measured electromagnetic field comprising:
comparing the filtered measured electromagnetic field with a predefined expected measurement data set, and
when the comparing result is within a predefined calibration threshold range:
   calibrating the analysis parameters for the electrode pair.

In-situ calibration is most important on missions lasting over a prolonged time, for example days, weeks and possibly months. Thus instead of premature termination of a mission, it may be possible to continue measurements with a new set of characteristic parameters for the electrode pairs.

According to some embodiments, the background noise is composed of noise generated by one or more of:
electromagnetic footprint of the underwater sensor platform, and
electromagnetic footprint of the environment.

According to some embodiments, further injecting the constant current signal periodically according to a first preset interval into the ambient water to provide an electromagnetic field around the underwater sensor platform.

According to some embodiments, further measuring the background noise periodically according to a second preset interval, and
adjusting the constant current signal strength to a level above the measured background noise.

According to some embodiments, further setting the first and/or the second preset intervals dynamically during deployment.

According to some embodiments, further determining from the measured electromagnetic field whether an electrode is to be replaced because it is either defect or has deteriorated past a predefined acceptable deterioration level.

According to some embodiments, further configuring the distinctive digital signal pattern and/or strength to be a pattern easily differentiable to the measured background noise.

It is provided for changing the injected constant current pattern, thus it is possible to avoid the case where the background noise is represented by a similar signal pattern deteriorating a possible test result.

According to some embodiments, dynamically altering the distinctive digital signal pattern to cover a range of frequencies ranging between 1 and 1000 Hz, or 1 and 100 Hz, or 1 and 10 Hz.

According to some embodiments, the underwater sensor platform further comprises:
a parent vessel/service, and
a communication module for communicating data related to the fault detection and calibration of electro-magnetic measuring system between the underwater sensor platform and the parent vessel/service, and the method further the method comprises the step:
communicating data related to the fault detection and calibration of electro-magnetic measuring system between the underwater sensor platform and a parent vessel/service.

According to a second aspect there is provided a system for fault detection and calibration of an electro-magnetic measuring system arranged on an underwater sensor platform, the system comprising: an underwater sensor platform, and an electro-magnetic measuring system arranged on the underwater sensor platform as define in any of the first, and a parent vessel/service.

According to some embodiments the underwater sensor platform is one of:
Autonomous Underwater Vehicle, AUV,
Remote Operated Vehicle, ROV, and
Underwater Intervention Drone, UID.

Effects and features of the second aspect are to a large extent analogous to those described above in connection with the first aspect. Embodiments mentioned in relation to the first aspect are largely compatible with the second aspect.

The present disclosure will become apparent from the detailed description given below. The detailed description and specific examples disclose preferred embodiments of the disclosure by way of illustration only. Those skilled in the art understand from guidance in the detailed description that changes and modifications may be made within the scope of the disclosure.

Hence, it is to be understood that the herein disclosed disclosure is not limited to the particular component parts of the device described or steps of the methods described since such device and method may vary. It is also to be understood that the terminology used herein is for purpose of describing particular embodiments only, and is not intended to be limiting. It should be noted that, as used in the specification and the appended claim, the articles “a”, “an”, “the”, and “said” are intended to mean that there are one or more of the elements unless the context explicitly dictates otherwise. Thus, for example, reference to “a unit” or “the unit” may include several devices, and the like. Furthermore, the words “comprising”, “including”, “containing” and similar wordings does not exclude other elements or steps.

### TERMINOLOGY

The term “constant current” is to be interpreted as substantially steadily supplied current from a constant current source, even if the load varies. When a pattern of the constant current source is used in present disclosure it shall be interpreted to comprise both when the constant current is provided in a distinctive digital (on off) pattern to distinguish it from background EM sources, and also when constant current is provided in alternating values, such as low current, high current, low current . . . in a pattern. The pattern may also comprise changing the polarization of the current direction in an alternating pattern. It shall also be understood as comprising a pattern altering between more than two values, also wherein one or more values have an opposite polarization. A constant current source will ensure the calibration current is always constant irrespective of the output impedance of the source electrodes, and also irrespective of the salinity of seawater.

The term “underwater sensor platforms”, shall beinterpreted as to comprise Autonomous Underwater Vehicle, AUV, Remote Operated Vehicle, ROV, Underwater Intervention Drone, UID, and the like. The techniques of the present disclosure may just as well be deployed on a towed, as a self-propelled, as a stationary underwater sensor platform.

The term “sea” shall be interpreted as any body of water wherein the underwater sensor platform/AUV may be deployed, it be an ocean, a lake, a river, a water containing installation, or similar.

The term “conductive fluid” shall be interpreted as any fluid, gel, or other that can act as a transfer medium of current.

The term “container” shall be interpreted as a conductive fluid holder.

### BRIEF DESCRIPTIONS OF THE DRAWINGS

The above objects, as well as additional objects, features and advantages of the present disclosure, will be more fully appreciated by reference to the following illustrative and non-limiting detailed description of example embodiments of the present disclosure, when taken in conjunction with the accompanying drawings.

FIG. 1 shows an AUV having at least two pairs of electrodes for measuring electromagnetic fields according to an embodiment of the present disclosure.

FIG. 2A shows an AUV having at least one pair of separate electrodes for injecting a controlled current signal, in a horizontal electric field, into ambient water according to an embodiment of the present disclosure.

FIG. 2B shows a similar setup as in FIG. 2A, in two modes, with opposite polarization in the injecting electrodes.

FIG. 2C shows an AUV having at least one pair of separate electrodes for injecting a controlled current signal, in a vertical electric field, into ambient water according to an embodiment of the present disclosure.

FIG. 2D shows an AUV having at least one pair in two modes, with opposite polarization in the injecting electrodes, of configurable source/receiver electrodes for injecting a controlled current signal, in a diagonal electric field, into ambient water according to an embodiment of the present disclosure.

FIG. 2E show a setup for simulation of electrode deployment mode for verification of electrode status pre-deployment of vessel.

FIG. 2F shows a cross section of the simulation setup in FIG. 2E.

FIG. 3 is a flow diagram of a method according to an embodiment of the present disclosure.

FIG. 4 is a diagram of connected modules of an embodiment of the present disclosure.

FIG. 5 Is a system overview of an embodiment of the present disclosure.

FIGS. 6A, 6B, 6C, and 6D illustrates various embodiments of patterns for the constant current signal being injected into the ambient water.

FIG. 7 illustrates an example of measured background noise.

FIG. 8A shows a block diagram of a setup of an embodiment for on shore/board testing of the electrodes.

FIG. 8B shows a block diagram for the electric signal path of the embodiment in FIG. 8A.

### DETAILED DESCRIPTION

The present disclosure will now be described with reference to the accompanying drawings, in which preferred example embodiments of the disclosure are shown. The disclosure may, however, be embodied in other forms and should not be construed as limited to the herein disclosed embodiments. The disclosed embodiments are provided to fully convey the scope of the disclosure to the skilled person.

The embodiments illustrated in the figures has been primarily been chosen as an Autonomous Underwater Vehicle, AUV. However as discussed above the techniques are optimized to be operating on any underwater vehicles, and in its widest interpretation it may even be deployed on fixed installations, such as drilling/production platforms, windmills, fish farms, ocean floor installations and the like.

The present invention is specifically advantageous when being deployed in an AUV/ROV/UID setting. For example, an AUV is self-sustained when it is powered and operating without any umbilical to a parent ship or any surface/on-shore installations. That means that the AUV has systems and power for operation of all equipment, both for propulsion and navigation, and also for operating on-board instruments and equipment. In that lays that when an AUV is submerged into the water for a mission, it is more or less alone. Although some communication to a parent installation may be maintained by low frequency communication signals that may travel in a water medium, all operation commands, instrument operation, data processing and other is advantageously residing in the AUV at launch time.

In present disclosure an improved advanced setup for testing the electrodes used in surveillance operations are provided.

There are numerous error prone entities and processes involved when operating an advances surveillance underwater sensor platform. Examples on causes for errors may involve:
faulty wire harness when mounting/servicing the internal instrumentation and sensors of the underwater sensor platform, including:
   wire shortage (earthed (to seawater))
   wire breakage (open connection)
   connecting path error
faulty sensors/electrodes (not operating)
deteriorated sensors/electrodes caused by:
   wear &tear
   age
   physical damage
   Obstruction/fouling/debris between the electrode and seawater

When an erroneous underwater sensor platform is launched it may take time and resources before such faults are detected, and since an underwater sensor platform may be deployed for long times, this may have fatal effects on the work that the underwater sensor platform is requested to do.

It is thus a great advantage if the underwater sensor platform is provided with methods and systems for detecting and if possible mitigate erroneous behavior in an autonomous manner.

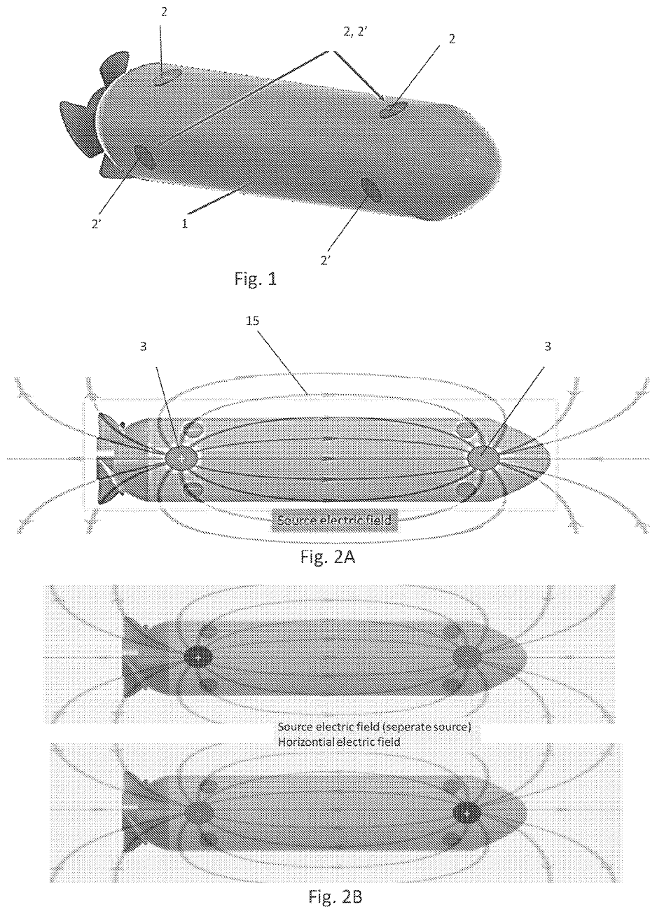

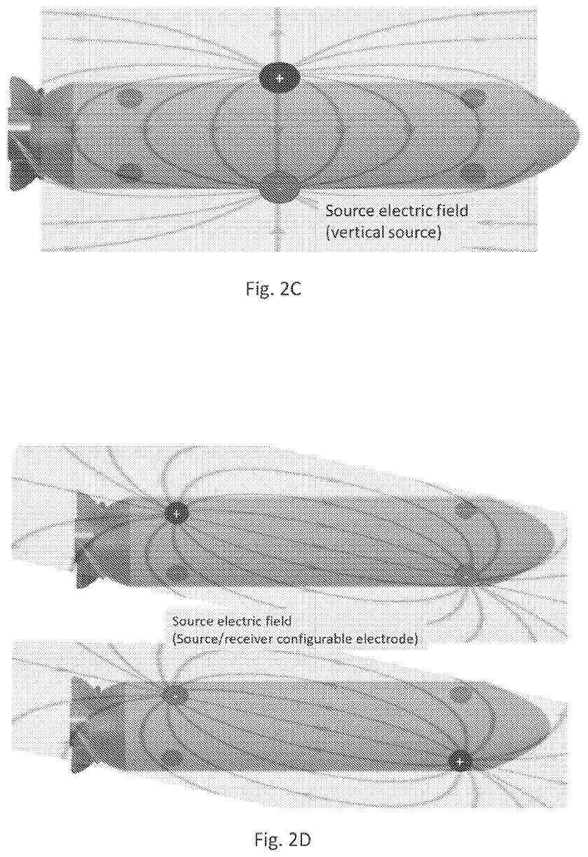

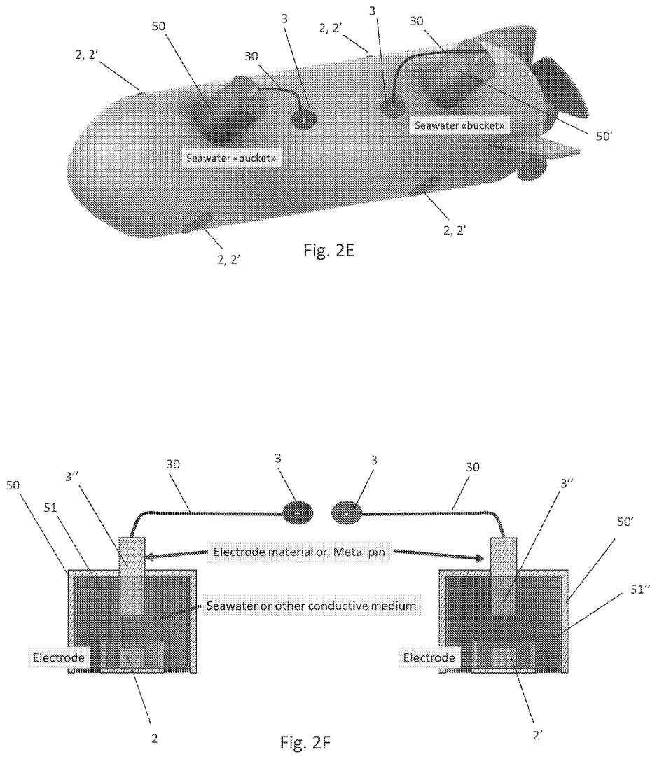

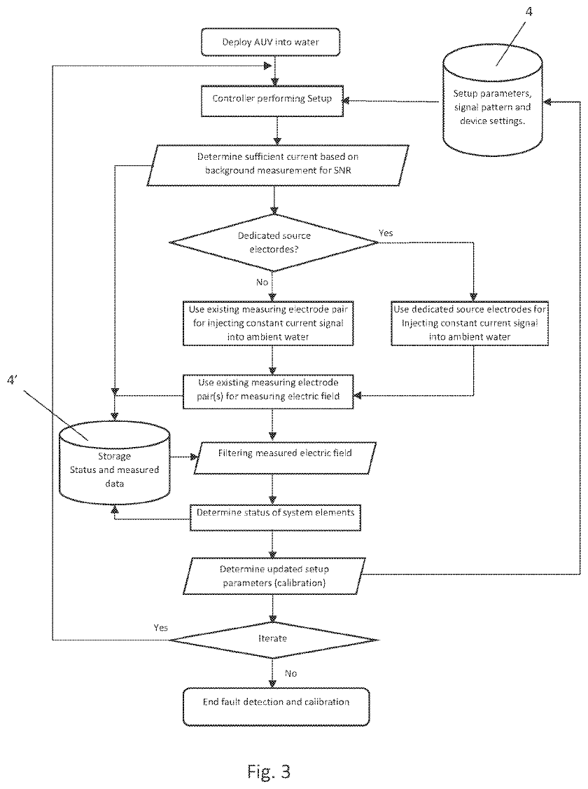

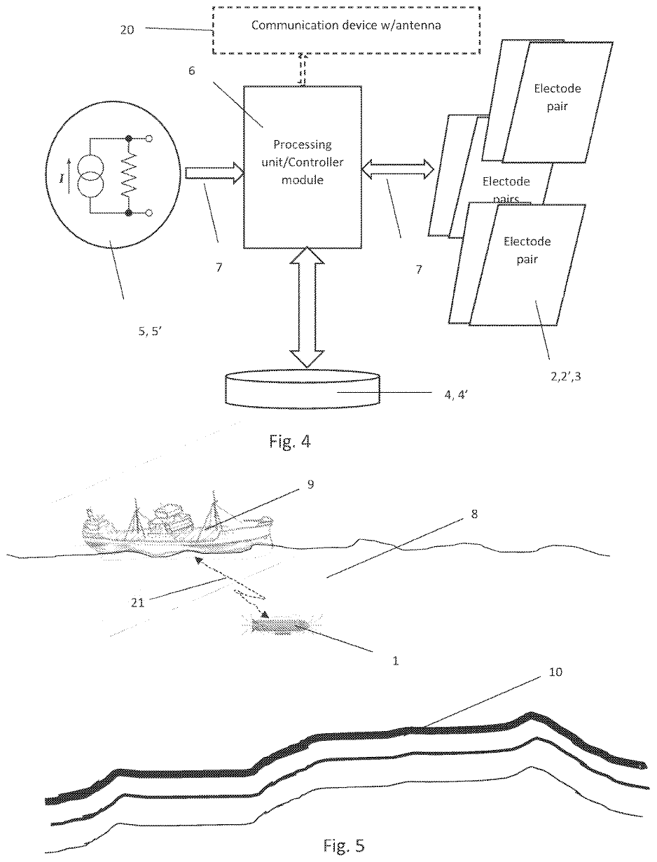

FIG. 1 and FIGS. 2A-2D shows multiple versions of an AUV according to embodiments of the present disclosure.

The first aspect of this disclosure shows a method for fault detection and calibration of an electro-magnetic measuring system arranged on an underwater sensor platform 1, the method comprising the steps:
providing an electro-magnetic measuring system in an underwater sensor platform 1, wherein the electro-magnetic measuring system comprising:
a first one or more electrode pairs 3 for injecting a controlled current signal into ambient water/conductive fluid,
a second one or more electrode pairs 2,2′ for measuring electromagnetic fields across the electrode pairs,
a power source 5,
a wire harness assembly 7 and a controller module/processing unit 6 for connecting to and controlling the first and second electrode pairs 2,2′,3 and data processing, and
   a constant/controlled current source 5′, powered by the power source 5, for providing a constant/controlleld current to the first one or more electrode pairs 3, the method comprising
the following steps:
   providing an on deck testing and calibration system comprising a pair of containers (50, 50′) mounted to any of the second one or more electrode pairs (2, 2′), wherein the containers (50, 50′) are filled with a conductive fluid (51, 51′), such that the electrodes (2, 2′) are fully surrounded by the conductive fluid (51, 51′), and further connecting a source electrode pair (3) and an embedded container source electrode/metal pin (3″) in each containers (50, 50′) via a connecting line (30), or
deploying the underwater sensor platform 1 into the sea, injecting a controlled voltage or constant/controlled current signal into ambient water/conductive fluid around the electrodes 2, 2′ with the first one or more electrode pairs 3, 3″.

The advantage with present disclosure is that it is provided an underwater sensor platform 1 with a self-contained/self-sustained method that can test itself during deployment by injecting a test signal in the form of a constant current signal into the ambient waters. Such that a known electromagnetic field around the underwater sensor platform 1 may be used for calibration and testing.

The underwater sensor platform 1 is set up with at least one power source 5 connected via the wire harness assembly 7 to the constant current source, the controller, the electrodes 2, 2′, 3 and optionally to a communication controller and communication device 20. The communication controller and communication device 20 being equipped with antenna(s) for communicating 21 with a parent entity on a ship 9 or surface/on-shore installation or the like (not shown).

Since the ambient waters 8 differ in characteristics, and the load it represent on any circuit it is fed by, it is an important feature of present disclosure to be able to provide a constant current into the ambient waters. This is required to be able to derive meaningful data when comparing measured field values with predefined expected dataset values.

The constant current is provided by a constant current source powered by a power source 5.

The system provided by the underwater sensor platform 1 may advantageously be used as a test and calibration system for a Cathode Protection system mounted on an AUV, ROV or UID.

The underwater sensor platform 1 may be provided such that the first one or more electrode pairs is one of:
one of the second one or more electrode pairs 2,2′ when there are more than one such electrode pairs provided on the underwater sensor platform 1, and
a dedicated pair of electrodes 3 used for injecting a current signal into ambient water.

When the constant current is injected in the ambient water 8 of the underwater sensor platform via the first one or more electrode pairs 3 it creates an electromagnetic field that is measured with the second one or more electrode pairs. Measurements made by the second one or more electrode pairs 2, 2′ is pairwise stored and investigated. The underwater sensor platform might be equipped by one or more such dedicated injecting electrode pairs 3.

When more than one pair of second electrode pairs 2, 2′ are comprised in the underwater sensor platform 1, it may be possible to use one pair of electrode pairs at a time as the injecting electrode pair for injecting the constant current into the ambient water 8. This way the manufacturing and wiring of the electrodes is kept at a minimum, and less parts being connected may be associated with fewer errors. When the injecting electrodes 3 are made up of a receiving electrode pair 2,2′ it is provided a controlling method wherein the controller 6 is programmed to periodically use one second electrode pair 2, 2′ for injecting current whilst reading electromagnetic field around the underwater sensor platform with any of the remaining electrode pair 2, 2′. The controller is repeating the process at least once such that the electrode being used for the injection of constant current is in the next phase used as a reading electrode pair for reading the electromagnetic field, here a different second electrode pair 2, 2′ is used as an injecting electrode pair.

Although the receiver electrodes, electrode pairs 2, 2′, do not normally source a current, they can, as discussed above, be configured to inject a small current/voltage, in the mV-mA region, and act as a low current EM source, see FIGS. 2B and 2D. This has the advantage of requiring no additional external cabling, and can transmit a calibration current through all 4 electrode pairs.

Thus by altering which electrode pair sending the test signal, all electrode pair may be evaluated, even when a dedicated electrode pair for injecting a current signal into ambient water is not installed in the underwater sensor platform.

It is obvious that an electromagnetic field around the underwater sensor platform may be influenced by many factors, such as for example background noise from for example other vehicles, including parent ship 9, the underwater sensor platform 1 itself with comprised equipment and units, reflected signals from the surrounding waters 8 and/or the sea bottom 10, and others. Background noise is exemplified by a measurement illustrated in FIG. 7.

For measurements done by the second one or more electrode pairs 2, 2′ it is important to take into account that these measurements also comprise a fair share of background noise as discussed above. It is thus important to know what portion of the detected signals are related to noise. It is suggested that the underwater sensor platform is provided with a periodic measurement of the background noise. This can be done with a dedicated reading session wherein the second one or more electrode pair 2, 2′, reads and store the background noise when no constant current is injected into the waters. This process may be done when the underwater sensor platform is operating all relevant features that may be operating during a real survey procedure except for the injection of constant current into the ambient water.

Once a proper reading has been read, processed and stored, this background data may be used in the following for filtering out similar data patterns from the next measurements being performed with the constant current field being provided by the injection of constant current from the electrode pair being used as the current injecting pair.

The method may thus further comprising one or more of the following steps:
measuring a background noise signal with the second one or more electrode pairs before injection of a constant current signal into ambient water,
providing the constant current signal as a distinctive digital signal pattern,
adjusting the constant current signal strength to a level above the background noise to ensure an acceptable SNR ratio,
measuring an electromagnetic field with the second one or more electrode pairs,
filtering the measured electromagnetic field.

The background noise may be measured periodically, for example once or every time before sets of measurements are performed with injected constant current. The periodicity of the measurement of the background noise may thus be adapted to the environment, the activity planned for the underwater sensor platform session, and the duration of the planned activities. Such that longer deployment may require many measurement sequences of the background noise with corresponding adjustment of the constant current signal strength to a level above the background noise during the mission.

In one embodiment the periodicity of the measurement of the background noise may be influenced by the analysis of the latest collected data when injecting constant current into the ambient water. For example: a situation wherein one or more electrode pair measurements are analyzed to be close to predefined threshold values it may be necessary to execute more frequent measurements of background noise with corresponding adjustments of the constant current signal strength. Therefore, the background noise measurement regime may vary dynamically, and scenarios for dynamically altering the periodicity of the background noise measurement regime and corresponding adjustments of the constant current signal strength may be predefined, and programmed and controlled by the controller.

The method may thus be provided for measuring the background noise periodically according to a second preset interval, and
adjusting the constant current signal strength to a level above the measured background noise such that an acceptable SNR is achieved.

It is thus provided for a system set up wherein the measured data may be cleaned for any unwanted influences, and the data may be used for analysis of the electrode and equipment health/error state.

The background noise is composed of noise generated by one or more of:
electromagnetic footprint of the underwater sensor platform 1, and
electromagnetic footprint of the environment 8,9,10.

A set of predefined expected data sets are provided to be used when analyzing the measured electromagnetic fields by the second one or more electrode pairs. The collected filtered data is then analyzed towards these predefined expected data sets, and depending on deviation from the expected data the electrode and/or harness assembly state may be derived. The analysis may be performed in-situ by the controller and controller logic/program. Since all data may be stored, some or all parts of the analysis may be done at a later stage upon return of mission by a remote, relative the underwater sensor platform, site after a data transfer has been provided. It is even possible to transmit some, analyzed or raw, data via the communication channel 21 to the parent ship or surface/on-shore installations for further analysis during mission. Typically this may be done if serious errors has been detected, and when an abort of the mission may be required, or fundamental change of mission parameters need to be implemented. Thus a remote site may send controlling parameters via the communication channel 21 to the mission and the controller 6. The controller then may be programmed to control the mission and the underwater sensor platform accordingly.

Thus when analyzing the filtered measured electromagnetic field, wherein, for each of the second one or more electrode pair 2,2′, the analysis of the filtered measured electromagnetic field comprise detecting one or more of:
an erroneously connected electrode,
a deteriorated or faulty harness assembly,
an erroneously wired harness assembly,
deterioration of the electrodes, and
changed characteristics in the ambient water 8.

Specifically the second last element above, when a deterioration of any of the electrodes are likely to have been detected, mitigating efforts may be initiated. The situation is likely to occur since the underwater sensor platform may operate in waters with high salinity and/or contaminating and corrosive components, and even if the sensors/electrodes 3, 2, 2′ do not operate with 100% efficiency/accuracy it is desirable to continue deployment when a mission is already ongoing. It is an aim to use the resulting data to calibrate the electrode/sensor. When such calibrating characteristics are considered the analyzed data may be adjusted for such electrode deteriorating effects.

It is worthwhile to dwell at the fact that also a dedicated first one or more pair of electrodes for injecting constant current into ambient waters maybe deteriorated. This may be detected by the controller controlling the constant current source, or it may be detected by certain recognizable errors in the detected resulting measured electromagnetic fields. Specific mitigating efforts maybe set in on a deteriorated injecting electrode pair, such as more frequent calibration processes, shorted missions before service can be executed, and other.

The method may thus comprise the step: analyzing the filtered measured electromagnetic field, wherein for each of the one or more electrode pair 2,2′,3 the analysis of the filtered measured electromagnetic field comprising:
comparing the filtered measured electromagnetic field with a predefined expected measurement data set, and
when the comparing result is within a predefined calibration threshold range:
   calibrating the analysis parameters for the electrode pair.

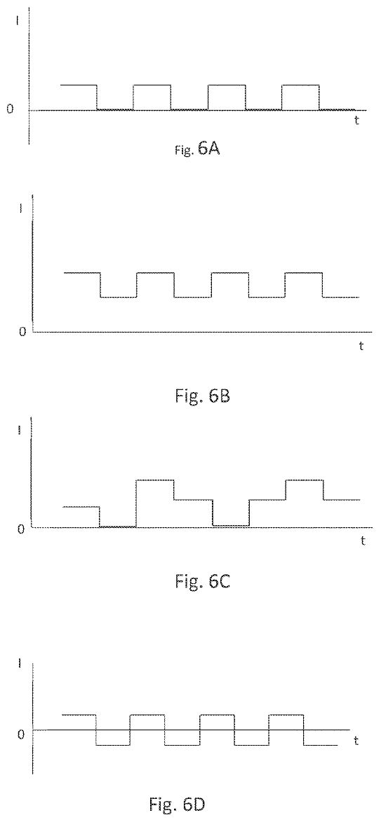

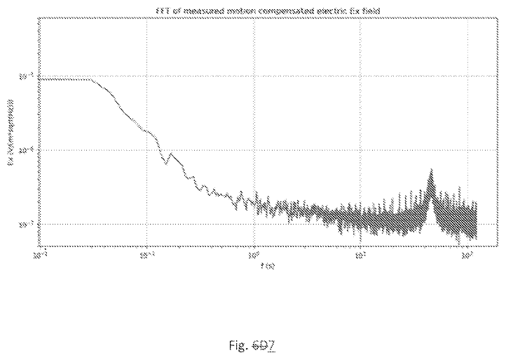

Background noise and other external factors may distort the capability to fully analyze the resulting data. Thus, it may be provided for injecting the constant current in a predefined pattern and strength, wherein the constant current is provided in an on off pattern, or the constant current may be provided in alternating values, such as low current, high current, low current and so on in a predefined pattern. The pattern may in a further embodiment comprise changing the polarization of the current direction in an alternating pattern. It shall also be understood that the pattern may be altered between more than two values, also wherein one or more values have an opposite polarization as seen in some non-limiting examples in FIGS. 6A, 6B, 6C and 6D.

The method according to present disclosure may comprise injecting the constant current signal periodically according to a first preset interval into the ambient water to provide an electromagnetic field 15 around the underwater sensor platform.

Any of the discussed intervals, the first preset interval for setting the pattern interval of the injected current, or the second preset interval for setting the interval for measuring the background noise may be dynamically defined during deployment/mission if called upon. This may be called upon for example when analyzed data falls within preset boundaries for changing any of the first or second preset intervals. Such dynamically changeable intervals may be predefined intervals stored in the controller.

The method may thus comprise setting the first and/or the second preset intervals dynamically during deployment.

The configuration of the distinctive digital signal pattern may be defined to be a pattern and/or strength easily differentiable to the measured background noise.

In one embodiment of the present disclosure the analyzed data may determine from the measured electromagnetic field that an electrode is to be replaced because it is either defect or has deteriorated past a predefined acceptable deterioration level. The determination may be stored for later use during above surface service of the underwater sensor platform, or it may be relayed through the communication channel 21 for immediate consideration at an above surface processing module/device/center.

Typically the signal pattern for the constant current is provided in a range between 1 and 1000 Hz, or in a further embodiment the signal pattern for the constant current is provided in a range between 1 and 100 Hz, or in a further embodiment the signal pattern for the constant current is provided in a range between 1 and 10 Hz. In an even further embodiment the pattern is dynamically altering the distinctive digital signal pattern to cover ranges between frequencies ranging between 1 and 1000 Hz, and/or 1 and 100 Hz, and/or 1 and 10 Hz.

The underwater sensor platform may be extended to comprise a remote service arranged on a parent vehicle 9, and a communication module 20 for communicating data between the underwater sensor platform and the parent vehicle related to the fault detection and calibration of electro-magnetic measuring system and/or controlling parameters for the controller 6, and the method further comprises the step: communicating data related to the fault detection and calibration of electro-magnetic measuring system between the underwater sensor platform 1 and a parent vessel/service 9.

The present disclosure thus proposes a fault detection and calibration method for an electro-magnetic measuring system providing:
1. Confirmation that electrode pairs are connected correctly
   a. No sensor harness failure/disconnects
   b. Electrode pair groups are connected correctly
2. fault detection and calibration of the electro-magnetic measuring system
   a. General fault detection and calibration
   b. Compensation for salinity
   c. Compensation for electrode aging

The electro-magnetic measuring system is designed to detect an electric field across electrode pairs. For example there may be 8 electric field sensors as illustrated in the FIGS. 2A-D, meaning 4 pairs of electrodes making up the complete measurement. In this manner the system is an excellent Electromagnetic (EM) measuring system.

The system is enhanced by injecting a precise current source periodically into seawater and using such injected current as a fault detection and calibration source that may confirm that the unit has no “dead” channels, and further enable ongoing system fault detection and calibration.

Generating a calibration signal is best performed using a controlled voltage/current source. This controlled signal can be injected into seawater in 2 possible ways.

In a first way as discussed above the current is injected through a dedicated pair of source electrodes. Such dedicated source electrode pairs may be placed in different locations, and may be more than one pair. FIG. 2A-2D illustrated a variation of embodiments providing horizontal, vertical and diagonal electric fields.

A second way is represented with, as also discussed above, using a receiver electrode pair as a source electrode pair. This enables a variety of configurations limited only by the numbers of receiving electrodes mounted in the system.

A third way is to design any of the electrodes with both a receiving electrode, and a source electrode. Such that when electrodes are installed, it is installed both a receiving electrode, and a source electrode at all of the locations, wherein the source electrodes are wired to connect directly to the voltage/current source via the controller 6. This way the calibration and test system does not need to take account for reduced voltage/current source limitation of a receiving electrode 2, 2′ used as a source electrode.

The injected voltage/current shall have a distinctive digital pattern to distinguish it from background EM sources.

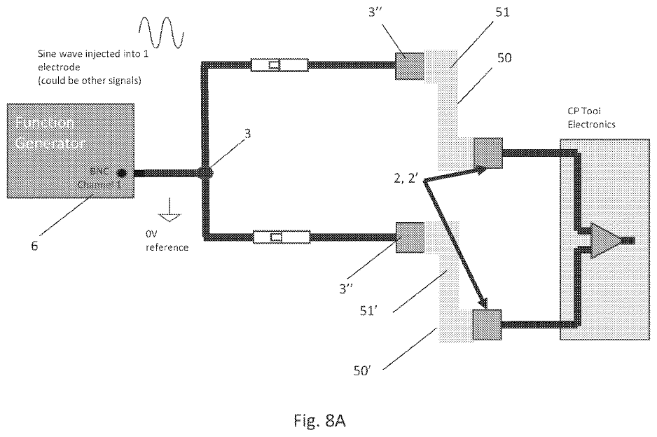

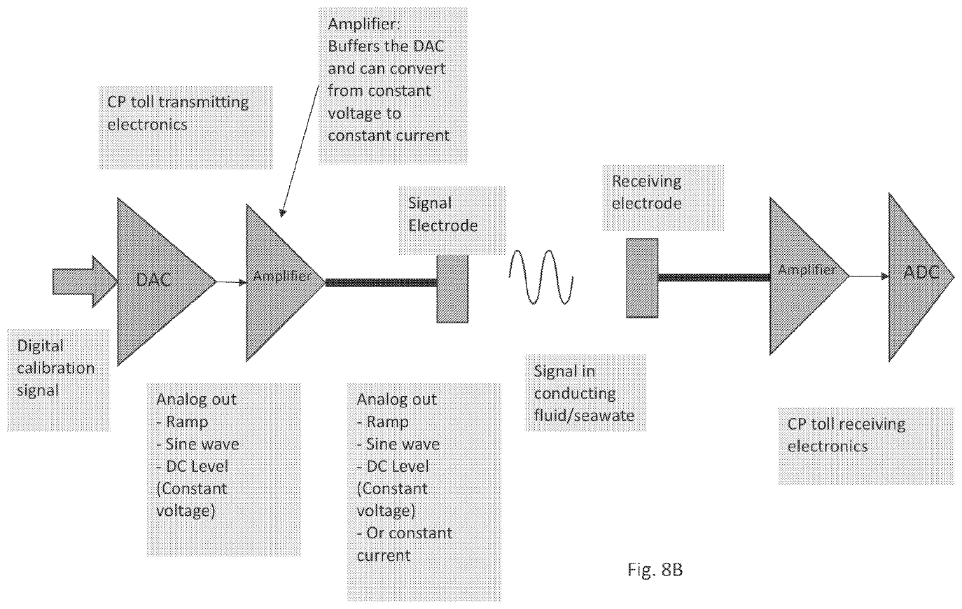

The system as described above can also facilitate calibration while the AUV is on deck, in a “dry” calibration mode as shown in FIGS. 2E, 2F, 8A and 8B.

The novel “dry” calibration mode calibration system may be used for calibration before deployment at sea, but equally effective be used under construction/manufacturing/assembly prior to mission deployment. The “dry” calibration mode system enables to simulate sea-deployment, providing real-life environment around the electrodes themselves by a confined environment around the receiving electrodes 2, 2′, for example with container 50, 50′ filled with conducting fluid 51, 51′ as shown in the figures. The container 50, 50′ maybe filled with a conductive fluid 51, 51′, for example seawater with known properties, or more advantageous for example a conductive fluid with comparable characteristics as the fluid the electrode is to be deployed in when on the next mission.

When a container 50, 50′ is arranged over/mounted to each electrode of an electrode pair 2, 2′ and filled with a conductive medium 51, 51′, such that each electrode 2, 2′ is immersed in the conductive medium 51, 51′ it is possible to use the same calibration source in either constant voltage or current mode to stimulate each electrode pair 2, 2′. This will put a +/− potential on each electrode, allowing a calibration and/or QC check while the AUV is not submerged i.e. on a back deck or even while the AUV in is in a laboratory (prior to shipping to a vessel).

The above could also be modified to having a direct electrical connection between each electrode material/metal pin, and the receiving electrode, without container and conductive medium (not shown).

It should be noted that in all cases, the potential applied to each electrode could be:
a fixed potential difference
A “digital” signal e.g. switched +/-potential difference, or
an analogue differential signal e.g. a sinewave

The digital or analogue inputs can be varied in amplitude, and frequency.

In a use scenario of the “on deck” calibration system as shown in FIGS. 2E and 2F, at least a pair of containers 50, 50′ are mounted on each of a pair of electrodes 2, 2′. The containers 50, 50′ are filled with a conductive medium 51, 51′, such as for example seawater with a known salinity. The electrodes 2, 2′ are thus fully surrounded by the conductive medium 51, 51′. A source electrode pair 3 and a container source electrode/metal pin 3″ embedded in each container 50, 50′ is connected via a connecting line 30. The source electrodes 3 comprise the source electrode pair. The polarity of the source electrode may be changed +/− in order to test all aspects of the electrodes 2, 2′. The setup may be used in all electrode configurations as discussed above. When the source electrode is provided with a controlled voltage/current, it will be possible to test the receiving electrode 2, 2′ health status. The conductive medium 51, 51′ may advantageously be comprised of water with salinity level equal to the estimated salinity level of the deployment waters have.

The testing of the receiving electrodes 2, 2′ of the underwater sensor platform 1 may thus as shown in FIG. 2E or 8A be tested on land (container), or in sea before a dive.

The “dry” calibration mode system, being executed in a dry environment have many advantageous over traditional test methods, such as:
No physical contact between testing probe 3″ and electrodes 2, 2′, thus damages from the test itself is maintained at a minimum
The test environment can be devised to be close to real life conditions, and thus mirroring a real life fault detection and calibration calibration method
The system is not restricted to be performed “at sea”, and is used as an initial sanity check, even before departing from the production site.
Since the test may be performed in, or immediately in connection with, production, it may act as a Quality Control, and ensure that no misconfiguration has happened before deployment.

When the configuration test is performed in deployment/sea-wet config the system have many advantageous over traditional test methods, such as:
No physical contact between source electrode 3 and electrodes 2, 2′, thus risk of damages from the configuration test itself is absent
The test environment is the real life conditions itself, and thus the real life deployment case is calibrated
The system may be used as periodic sanity check of the source, harness and electrodes

In FIGS. 8A and 8B there is provided a “dry” calibration mode wherein the signal imposed on the container source electrode/metal pin 3″ is provided by a function generator acting as a second controller module/processing unit 6′. By introducing a function generator as the source provides for unlimited signal patterns. The function generator may be comprised of a Burst Noise Channel, BNC Channel. As seen in FIG. 8B it is provided both an Digital To Analog converter step and an amplifier step, representing the voltage/current source. A lot of variations in signal pattern maybe imposed on the electrodes, such as, but not limited to: ramp, sine wave, DC level (Constant voltage) or constant current. A similar function generator may be used in the wet configuration for imposing signals to the source electrodes 3.

Further in the “dry” calibration mode, there is provided an enclosed environment in the containers 50, 50′, being filled with the conducting fluid 51, 51′. The container source electrode/metal pin 3″ is embedded in the container and is in electrical contact with the conducting fluid. The container 50, 50′ itself is made of a non-conducting material, such as for example, but not limited to: plastic, polymers or ceramics. There is no physical requirements to the form of the container as long as it can provide a low impedance path for the signal between the source and the receiving electrode 2, 2′.

The conducting fluid 51, 51′ provides a conductive path between the container source electrode/metal pin 3″ and the corresponding receiving electrode 2, 2′. It is thus provided a simple, controlled environment for testing the receiving electrodes 2, 2′. And advantageously, it may be sufficient to provide voltage/current in mV/mA interval.

In FIG. 8B it is shown how the signal path may be provided from an input to a Digital To Analog Converter, via an Amplifier, and to the signal electrode via a wire harness. The signal then propagates through a conductive fluid and being picked up by the receiving electrode. From the receiving electrode the signal is transmitted via wire harness to an amplifier and then to an Analog To Digital converter.

The second aspect of this disclosure shows a system for fault detection and calibration of an electro-magnetic measuring system arranged on an underwater sensor platform, the system comprising: an underwater sensor platform, according to the first aspect and an electro-magnetic measuring system arranged on the underwater sensor platform 1 as define above, and a parent vessel/service 9. The parent service 9 may be an on shore or above surface installation.

The person skilled in the art realizes that the present disclosure is not limited to the preferred embodiments described above. The person skilled in the art further realizes that modifications and variations are possible within the scope of the appended claims.

Additionally, variations to the disclosed embodiments can be understood and effected by the skilled person in practicing the claimed disclosure, from a study of the drawings, the disclosure, and the appended claims.

1-16. (canceled)

17. A method for fault detection or calibration in an unsubmerged state of an electro-magnetic measuring system arranged on an underwater sensor platform, the method comprising the steps:
providing an underwater sensor platform comprising an electro-magnetic measuring system, wherein the electro-magnetic measuring system comprising:
one or more electrode pairs for measuring electromagnetic fields across said electrode pairs;
a power source;
a wire harness and a first controller module configured for data gathering and/or processing, the wire harness connecting the first controller module to the one or more electrode pairs;
the method comprising the following steps:
providing one or more pair of containers comprising an electrode material, and a function generator acting as a second controller module/processing unit and source for providing signal patterns;
mounting the containers to any of the one or more electrode pairs;
filling the containers with a conductive fluid, such that the electrodes of the one or more electrode pairs are immersed in the conductive fluid, and further connecting, via a connecting line, the function generator to the electrode material embedded in each container via a connecting line;
injecting by the electrode material and the function generator a controlled voltage or controlled current signal into the ambient conductive fluid around the electrodes;
measuring an electromagnetic field with the one or more electrode pairs; and
analyzing the measured electromagnetic field, wherein for each of the one or more electrode pair the analysis of the measured electromagnetic field comprise verifying nominal system behavior and/or detecting deviations from expected result.

18. The method according to claim 17, wherein the function generator providing a variety of signal patterns comprising one or more of: ramp, sine wave, constant voltage or constant current.

19. The method according to claim 17, wherein the container is made of a non-conducting material, such as one of: plastic, polymers or ceramics.

20. The method according to claim 17, wherein the detected deviation from expected result is caused by one or more of:
an erroneously connected electrode,
a deteriorated or faulty harness,
an erroneously harness, and
deterioration of the electrodes.

21. The method according to claim 17, further comprising the step:
analyzing the measured electromagnetic field, wherein for each of the one or more electrode pair the analysis of the measured electromagnetic field comprising:
comparing the measured electromagnetic field with a predefined expected measurement data set, and
when the comparing result is within a predefined calibration threshold range:
calibrating the analysis parameters for the electrode pair.

22. The method according to claim 17, comprising determining from the measured electromagnetic field whether an electrode is to be replaced because it is either defect or has deteriorated past a predefined acceptable deterioration level.

23. The method according to claim 18, further dynamically altering the constant current signal as a distinctive digital signal pattern to cover a range of frequencies ranging between and 1000 Hz, or 1 and 100 Hz, or 1 and 10 Hz.

24. The method according to claim 17, wherein the underwater sensor platform is one of:
Autonomous Underwater Vehicle, AUV;
Remote Operated Vehicle, ROV; and
Underwater Intervention Drone, UID.

25. A system for fault detection and calibration of an electro-magnetic measuring system arranged on an underwater sensor platform, the system comprising:
an underwater sensor platform, comprising:
one or more electrode pairs for measuring electromagnetic fields across said electrode pairs;
a power source;
a wire harness and a first controller module configured for data gathering and/or processing, the wire harness connecting the first controller module to the one or more electrode pairs; and
the system further comprising:
one or more pair of containers comprising an electrode material, and
a function generator configured to act as a second controller module/processing unit and source for providing signal patterns;
the containers are mounted to any of the one or more electrode pairs, the containers are filled with a conductive fluid, such that the electrodes of the one or more electrode pairs are immersed in the conductive fluid, and further the function generator is connected via a connecting line to the electrode material embedded in each container; and
the system is arranged on the underwater sensor platform and is configured to execute the method as define in claim 17.
